(19) United States
(12) Patent Application Publication
(10) Pub. No.: US 2016/0027950 A1
(43) Pub. Date: Jan. 28, 2016

(54) Methods Of Low-Temperature Fabrication Of Crystalline Semiconductor Alloy On Amorphous Substrate

(71) Applicant: The Trustees of Dartmouth College, Hanover, NH (US)

(72) Inventors: Jifeng Liu, Hanover, NH (US); Haofeng Li, West Lebanon, NH (US); Xiaoxin Wang, Hanover, NH (US)

(21) Appl. No.: 14/878,849

(22) Filed: Oct. 8, 2015

Related U.S. Application Data
(63) Continuation-in-part of application No. 13/401,206, filed on Feb. 21, 2012.
(60) Provisional application No. 62/061,620, filed on Oct. 8, 2014.
(60) Provisional application No. 61/590,660, filed on Jan. 25, 2012.

(51) Int. Cl. H01L 31/0687; H01L 31/0232; H01L 27/144; H01L 31/103; H01L 31/109; H01L 31/18; H01L 31/0725

(52) U.S. Cl. CPC H01L 31/0687; H01L 31/1864; H01L 31/1812; H01L 31/1844; H01L 31/02325; H01L 31/0725; H01L 31/103; H01L 31/109; H01L 27/1446

(57) ABSTRACT

Methods are discussed for producing single-crystal shapes on amorphous materials. A first method deposits a layer of Germanium-Tin (GeSn) alloy comprising between three and sixteen atomic-percent tin on material incapable of seeding crystal formation, the layer is photolithographically defined into a shape having a point having radius less than 100 nanometers; and the shape is annealed by heating to a temperature below 450 degrees Celsius. A second method also photolithographically defines a shape on a layer of GeSn, then uses a laser to heat and crystalize seed spot on the shape; and anneals the shape by heating and thereby crystalizing additional GeSn alloy of the shape. In embodiments, the crystalized GeSn serves to seed InGaP and/or InGaAs layers that may serve together with the GeSn as layers of a tandem photovoltaic cell.

### RELATED APPLICATIONS

The present application claims priority to U.S. Provisional Patent Application 62/061,620 filed 8 Oct. 2014. The present application also is a continuation-in-part of U.S. patent application Ser. No. 13/401,206 filed 21 Feb. 2012 which in turn claims priority to U.S. Provisional Patent Application Ser. No. 61/590,660 filed Jan. 25, 2012 the contents of the aforementioned patent applications are incorporated herein by reference.

### GOVERNMENT RIGHTS

This invention was made with government support under DMR-1255066 awarded by the National Science Foundation. The government has certain rights in the invention.

### BACKGROUND

All else being equal, semiconductor devices fabricated in single crystal or near-single-crystal materials are well known for better performance than those fabricated in polycrystalline or amorphous materials because there are fewer charge-recombination sites and less junction leakage. Electro-optical devices, such as photosensors, fabricated in single crystal materials therefore often have improved sensitivity over those fabricated in polycrystalline or amorphous materials; these photosensors may also have sensitivity that is more uniform across the thousands of photosensors of an array photosensor circuit. Similarly, photovoltaic cells fabricated in single-crystal materials often have greater energy conversion efficiency than those fabricated from polycrystalline or amorphous materials.

Low bandgap materials, such as Ge—Sn (Germanium-Tin alloy), can be used to fabricate electro-optical devices operating at optical communications wavelengths greater than 1.3 microns, such as photosensors and electro-absorption modulators, that operate a much longer wavelengths than can devices fabricated directly in higher bandgap materials such as silicon. Furthermore, GeSn alloy is a direct-bandgap semiconductor for Sn atomic percentage greater than 7 at. %, meaning that the material has far superior optoelectronic properties than indirect-bandgap semiconductors such as silicon (Si).

Voltage produced by photovoltaic cells increases with bandgap of the semiconductor from which they are fabricated, so photovoltaic cells formed of high-bandgap semiconductors have higher energy conversion efficiency at short wavelengths of light than do cells formed of low-bandgap materials. High-bandgap semiconductors, however, are less efficient at absorbing longer wavelengths of light, and become transparent to light having photon energy below their bandgap. High conversion efficiency “tandem” photovoltaic devices may be produced by layering photovoltaic cells formed of high bandgap materials over cells formed of low bandgap materials, such that short wavelengths are absorbed in the high bandgap materials, and longer wavelengths are absorbed in the low bandgap materials.

The fabrication of general purpose electronics, including row decoders, column sense amplifiers, analog-to-digital and digital-to-analog converters, digital signal processors, high speed multiplexors and demultiplexers, and similar circuitry in single-crystal silicon is far more advanced than fabrication of similar electronic devices in low-bandgap materials. Some companies have therefore striven to combine silicon circuitry, with electro-optical devices, such as photosensors, lasers, or light-emitting diodes, formed in low-bandgap materials, so that each material may be used where it functions best. Such combinations of silicon circuitry with low-bandgap electrooptical devices are expected to be of use in infrared and thermal imaging, as well as in telecommunications.

Among prior attempts at combining silicon circuitry with low-bandgap or direct bandgap semiconductor devices are hybrid devices formed by bonding a low-bandgap/direct-bandgap semiconductor wafer to a silicon wafer. Other devices have been formed by growing a low-bandgap/direct-bandgap semiconductor material epitaxially directly over a single-crystal substrate, such that the single-crystal substrate serves as a crystal growth seed for the overlying low-bandgap/direct-bandgap material. Epitaxial growth of low-bandgap/direct-bandgap material on silicon, however, works best with materials having a crystal lattice structure similar to that of the silicon; materials having dissimilar crystal lattice pitch than the substrate, for example, are difficult to grow without introducing stacking defects and strain. In particular, few other semiconductors have a crystal lattice well matched to silicon, and most lack the low bandgap/direct-bandgap required for medium or long-wave infrared applications.

### SUMMARY

Methods are discussed for producing single-crystal Germanium-Tin (GeSn) shapes on amorphous materials, and devices produced by those methods are disclosed.

A first method deposits a layer of (GeSn) alloy comprising between three and sixteen atomic percent tin on material incapable of seeding crystal formation (e.g., amorphous materials), the layer is photolithographically defined into a shape having a point having radius less than 100 nanometers; and the shape is annealed by heating to a temperature between 200 and 450 degrees Celsius.

A second method for producing single-crystal shapes on amorphous materials also provides a layer of GeSn, then uses a laser to heat and crystalize a seed spot on the shape; and anneals the shape by heating and thereby crystalizing additional GeSn alloy of the shape.

### BRIEF DESCRIPTION OF THE FIGURES

FIG. 1 shows a perspective view of a portion of a semiconductor device incorporating a single crystal or pseudo single crystal nanotaper shape, in an embodiment.

FIG. 2 is a cross sectional diagram illustrating a single-crystal nanotaper shape of FIG. 1 as an optoelectronic component integrated with silicon CMOS components in an integrated circuit, in an embodiment.

FIG. 3 is a flowchart of a portion of a method of manufacture of the integrated circuit of FIG. 2 and shape of FIG. 1, in an embodiment.

FIG. 4 is a detail view of recrystallizing GeSn at the nanotaper shape of FIG. 1, showing tin released during recrystallization.

FIG. 5 is a top plan view of an alternative embodiment where an spot on a rectangular shape is laser heated to trigger formation of a seed spot, the seed spot expanding during an anneal to fill a seed shape with single-crystal GeSn.

FIG. 5A is a top view of a GeSn shape, showing a seed spot and seed line.

FIG. 6 is a flowchart of a method associated with the alternative embodiment of FIG. 5.

FIG. 7 is an illustration of bandgap versus lattice pitch for certain semiconductor materials, including GeSn.

FIG. 8 is a cross sectional illustration of a three-layer photovoltaic cell illustrating GeSn, InGaAs and InGaP active layers.

FIG. 9 is a cross sectional illustration of a tandem photovoltaic cell illustrating InGaAs and InGaP active layers, with a GeSn seed layer.

### DETAILED DESCRIPTION

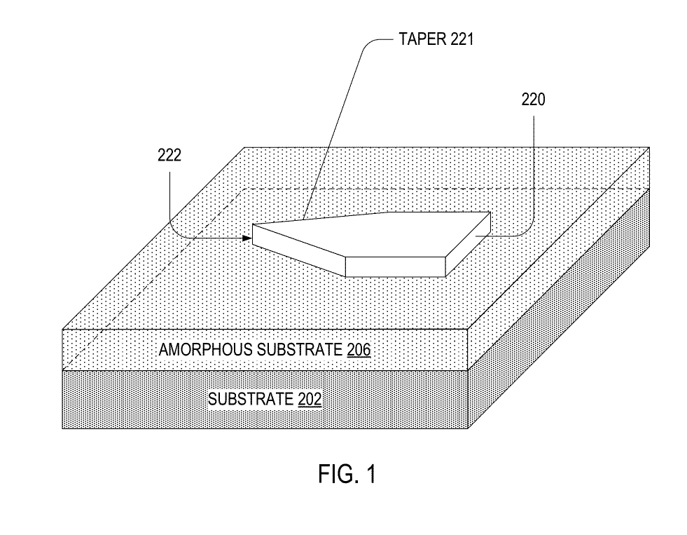

FIG. 1 shows a single-crystal semiconductor shape 220 on an amorphous layer 206, where single-crystal semiconductor shape 220 in some embodiments is formed of a low bandgap material; in a particular embodiment shape 220 is formed of germanium-tin (GeSn) alloy. Single-crystal semiconductor shape 220 includes a nanotaper 221, which has a tip 222. The tip of the taper structure has a diameter less than 100 nanometers (nm), and in a particular embodiment less than 80 nm, to depress a eutectic melting point and nucleation temperature of the tip. Amorphous layer 206 may in some embodiments be a substrate, or in other embodiments is formed over a substrate 202. Single-crystal semiconductor shape 220 in some embodiments is formed of a germanium-tin alloy (GeSn), Ge₁₋ₓSnₓ, where 0<x<0.5, alloys having up to 50 at. % tin. In a particular embodiment, x=0.1. The GeSn alloy in some functional embodiments has between 3 and 16 at. % tin, and much of our work has used between 10 and 11.5 at. % tin content. The GeSn alloy of shape 220 is between one nanometer and one micron thick.

In typical embodiments, amorphous layer 206 is a polyimide, a chemical-vapor-deposited (CVD) silicon dioxide glass, or a silicon oxynitride glass. In other embodiments, amorphous layer 206 is an electrically conductive metal. Amorphous layer 206 may include more than one layer of more than one type of material, so as to provide electrically conductive, including metal, and electrically insulating, including glass or polymer layers, and may include microcrystalline portions as well as amorphous portions. Amorphous layer 206 is typically incapable of seeding crystal formation by itself because it lacks sufficient ordered crystal structure. In embodiments where amorphous layer 206 lies over a single-crystal substrate 202, such as embodiments where substrate 202 is a silicon wafer or die in which electronic circuitry is formed, there are no openings in amorphous layer 206 that permit contact of semiconductor shape 220 to single-crystal substrate 202.

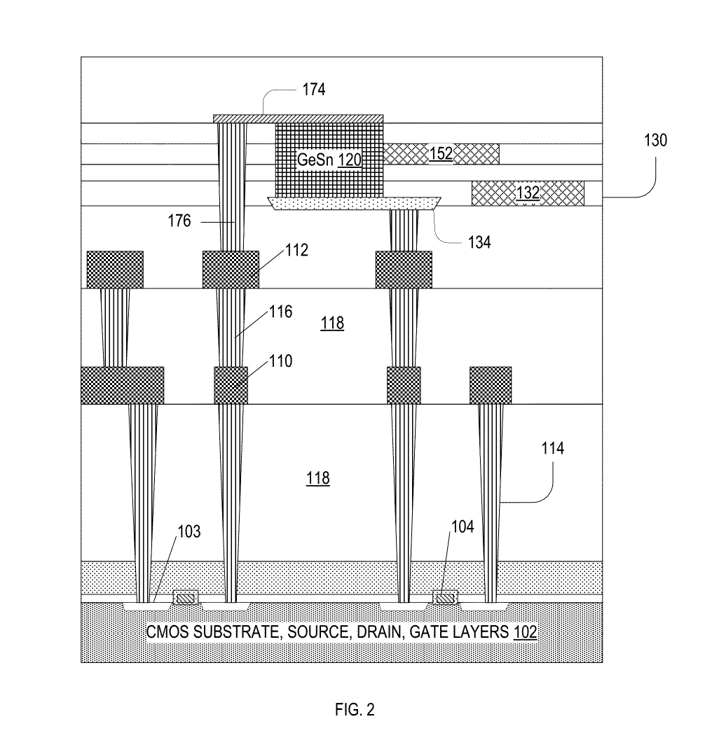

Additional layers of material, such as electrically conductive layers, including transparent metal-oxide conductive layers such as indium-tin-oxide, and/or electrically insulating layers, may cover the semiconductor shapes 120, 220. (FIGS. 1 and 2).

A particular embodiment where single-crystal shape 220, 120 is formed over a CMOS IC is illustrated in FIG. 2. A standard CMOS substrate wafer 102, having N and P wells (not shown) with source and drain diffusions 103, gate oxide, and polysilicon gate 104 has electronic circuitry formed in and on the CMOS substrate 102, as known in the CMOS fabrication art. One, two, or more layers of metal interconnect 110, 112, metal-to-metal vias, which may be filled with metal plug 114, 116, and dielectric layers 118 are deposited over the CMOS substrate 102 and gate 104. The dielectric layers 118 may include oxide layers, such as CVD-deposited silicon dioxide, and/or high-temperature insulating polymer layers such as polyimide layers, the metal interconnect and vias are patterned by photolithographic masking and etching as known in the CMOS multilevel-metal semiconductor art.

In an embodiment, among layers built on top of CMOS substrate, is microcrystalline or amorphous layer 134 provided to serve as a substrate and may also serve as an electrical contact for single-crystal or pseudo-single-crystal shape 120; when formed of metal amorphous layer 134 may also serve as a metal interconnect layer, and in an embodiment where photosensors are formed in crystal shape 120, amorphous layer includes an electrically conductive layer or sublayer. When amorphous layer 134 includes an electrically conductive layer, it is anticipated that amorphous layer 134 may include either a metal or a heavily-doped semiconductor as a layer or as a sublayer within layer 134.

In some but not all embodiments, one or more optical waveguide layers 132, 152 are provided for optically coupling optoelectronic components built into single crystal shape 120. Where optoelectronic devices are formed in single-crystal shape 120 and coupled into adjacent waveguide structures 132, 152, these waveguides are referred to as lateral waveguides.

In this embodiment, atop single-crystal or pseudo-single-crystal shape 120 is deposited a top-contact layer 174, which in embodiments where light is to be emitted or absorbed from above is a transparent, electrically conductive, metal-oxide contact layer such as, but not limited to, indium tin oxide (ITO); some such embodiments may reinforce conductivity of transparent oxide with a grid of conductive metal. Where optoelectronic devices formed in single crystal shape 120 couple into waveguides through a top contact layer, these waveguides are referred to as vertical waveguides. In embodiments where optical components built in shape 120 are coupled into waveguides 132, 152, top contact layer 174 may be formed from a metal or heavily doped non-transparent semiconductor. Both amorphous layer 134 and top contact layer 174 may be coupled to other electrically conductive metal layers by vias 176. Additional layers, which may include optical filter layers as well as passivation and protection layers, are formed over top-contact layer 174.

It is anticipated that single-crystal-shape 120 may be formed from germanium-tin alloy, and may, in different embodiments, be used to form optoelectronic devices such as PN or PIN photodiodes, Shottky-barrier photodiodes, lasers, and electro-optical modulators; since GeSn has a low bandgap these devices may be functional at long wavelengths such as wavelengths between one and three microns.

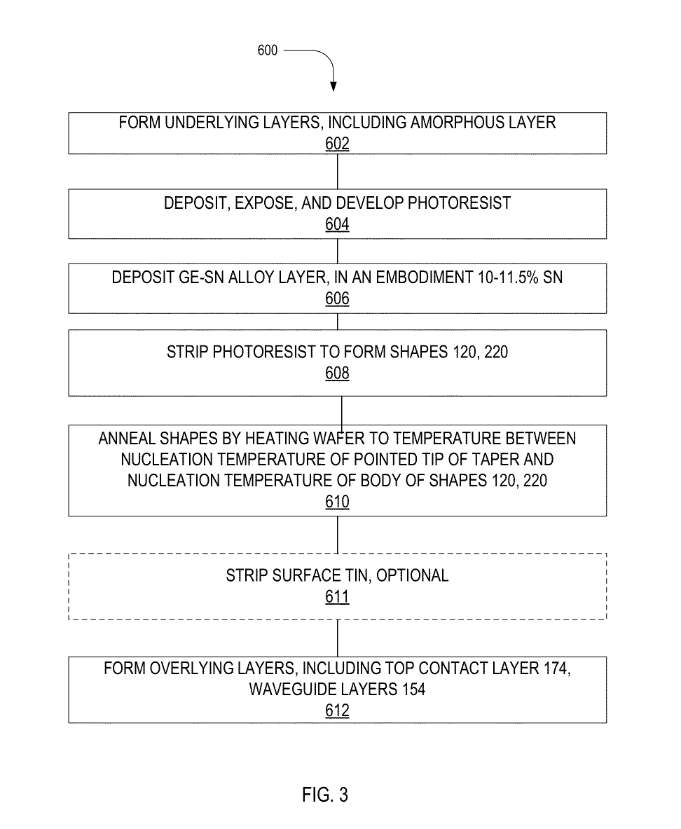

FIG. 3 is a flowchart illustrating an exemplary method 600 for fabricating assembly single-crystal or near-single-crystal shape 120, 220. The method begins with forming 602 all layers, such as CMOS substrate 102, 202, interconnect metal 110, 112, vias 116, and amorphous layer 134, that will lie underneath shape 120.

In embodiments using a lift-off process for patterning single-crystal or near-single-crystal shape 120, 220 into the nanotaper shape the process continues with depositing, exposing, and developing a photoresist 604. An amorphous layer of germanium-tin (GeSn) alloy having from 10% to 11.5% atomic-percent is then deposited 606 over the developed photoresist and amorphous layer 134. The photoresist is then stripped 608 to form shapes 120, 220. In an alternative embodiment, shapes 120, 220, including nanotaper 221, are formed by depositing the GeSn alloy, then depositing, exposing, and developing a photoresist, followed by a plasma etch to remove undesired GeSn alloy, and stripping the photoresist. After the shapes are formed, they are annealed by heating 610 the wafer to temperature between a nucleation temperature of a pointed tip of taper and a nucleation temperature of body of shapes 120, 220; in a particular embodiment having small-radius tips 420 degrees Celsius. The temperature to which the wafer is heated may vary somewhat with tip radius and process conditions, but will lie between 400 and 450 degrees. Once the shapes 120, 220 are formed and annealed, excess tin that has formed a coating on the GeSn surface during recrystallization may optionally be removed 611 with a selective acid bath, and they may be covered with additional layers required for particular embodiments, such as top contact layer 174.

When it is desired to form large shapes of monocrystalline GeSn, a nanotaper shape as previously described is used in an embodiment to form a nanotaper shape seed crystal in contact with the larger shape. The seed crystal is then extended by annealing or laser recrystallization throughout the large shape to recrystallize the large shape as a single-crystal shape.

In an alternative embodiment, the nanotaper shape is formed by depositing the GeSn material and defining the nanotaper shape 221 by laser scribing.

Theoretical Analysis

When there is a high curvature surface, such as the tip of a nanotaper, the local melting temperature decreases with the tip radius r as described by the Gibbs-Thomson Equation.

$${T}_{m} ( r ) = {T}_{m} ( ∞ ) - \frac{2 {T}_{m} ( ∞ ) {σ}_{sl}}{Δ {H}_{f} ( ∞ ) {ρ}_{s} r} \qquad ( 1 )$$

where Tₘ (r), Tₘ (∞), σₛₗ, ΔH_{f} (∞), and ρₛ are the nanotip melting temperature, bulk material melting temperature, solid-liquid interfacial energy, heat of fusion of the phase transition, and the atomic density of the solid phase, respectively. In Ge—Sn system, we have found that the nucleation of Ge-rich GeSn crystals from its amorphous state is initiated by the eutectic phase transition above the eutectic temperature. Since the composition of the eutectic point is almost pure Sn (99.74 at. % Sn) while the composition of Ge-rich solid phase remains almost the same before and after the eutectic transition, we can approximate this eutectic phase transition process by considering the melting of Sn in Ge-rich GeSn. Therefore, if we fabricate a GeSn nanotaper structure with a high-curvature tip, during annealing the tip will undergo eutectic transition earlier than the rest of the GeSn regions due to the lower eutectic temperature. Consequently, nucleation should start preferably at the high-curvature tip, which can be applied to seed the single crystal GeSn growth. From the equilibrium phase diagram of Ge—Sn, above the eutectic temperature (231° C.) an almost pure (99.74 at. % Sn) liquid Sn phase coexists with a Ge-rich solid phase (1 at. % Sn). Even considering that the phase transition starts with non-equilibrium a-GeSn in our case, the liquid phase is still nearly pure Sn and the solid phase is still highly Ge-rich (˜10 at. % Sn). Therefore, when considering the eutectic temperature depression at the tip, the term σₛₗ in Eq. 1 can be well approximated by the interfacial energy between liquid Sn and solid Ge phase, which is 0.548 J/m². Based on the same considerations, ΔH_{f} (∞) and ρₛ are approximated by that of β-Sn, which are 7.03 kJ/mol and 6.205×10⁴ mol/m³ respectively. As we can see, the eutectic temperature depression is >5° C. at tip radius <100 nm. When the tip radius is ˜50 nm, the tip eutectic temperature is ˜13° C. lower than the bulk eutectic temperature. From our previous investigations on the crystallization of amorphous GeSn, it was found that this eutectic temperature in amorphous GeSn thin films seems to be higher than what is described in the equilibrium phase diagram. From Eq. 1, we can find that this would lead to an even more significant eutectic transition temperature depression, which is more beneficial for the preferential nucleation at the tip.

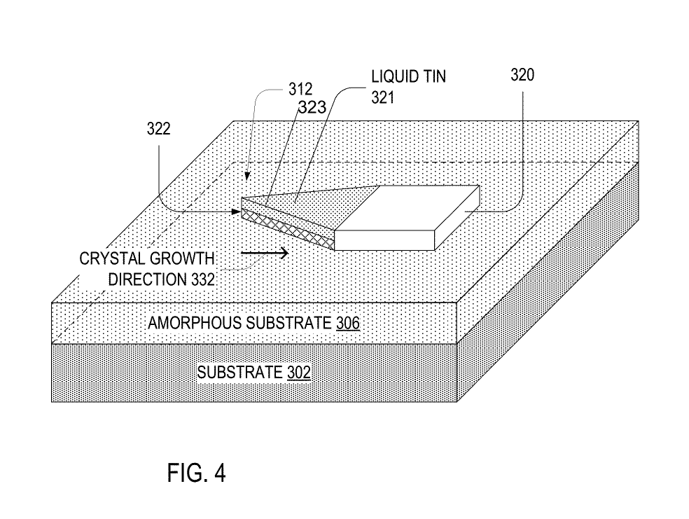

For the purposes of this discussion, the nanotaper includes two sections: a bulk portion and a tip. The tip of the taper structure has a diameter less than 100 nm, and in a particular embodiment less than 80 nm to depress a eutectic melting point and nucleation temperature of the tip through the Gibbs-Thompson effect. In an example of annealing step 610, method 600 forms an amorphous GeSn (herein, “a-GeSn”) shape 320 on an amorphous substrate 306, as shown in FIG. 4. Shape 320 includes a nanotaper 323, which has a tip 312. In an embodiment, tip 312 has a radius of curvature R_{c}<100 nm. Amorphous substrate 306 is similar to amorphous substrate 102, 202 (FIGS. 1 & 2) and lies on any additional substrate 302 that may optionally be present in the device.

The small value of Rc significantly increases the surface energy per unit volume at the tip of the taper relative to adjacent surfaces. This facilitates liquid-solid phase separation above the eutectic temperature. Consequently, the required nucleation temperature Tₙ for liquid-solid phase separation and subsequent Ge-rich GeSn nucleation at the tip of the taper (Tₙ=Tₙ_{_{—}}ₜᵢₚ) can be significantly lower than the rest of the a-GeSn nanotaper (Tₙ=Tₙ_{_{—}}_{bulk}): Tₙ_{_{—}}ₜᵢₚ<Tₙ_{_{—}}_{bulk}<500° C.

In step 610, the method of FIG. 3 anneals the shape at a temperature between the nucleation temperature of the nanotaper tip and the nucleation temperature of the bulk portion of the nanotaper. This results in a nucleation process confined at the nanotaper tip. The nanoscale geometrical confinement at the nanotaper tip greatly facilitates the formation of a single nucleus, which is strongly driven by interface energy minimization.

In step 610, annealing is done at a temperature T, wherein Tₙ_{_{—}}ₜᵢₚ<T<Tₙ_{_{—}}_{bulk}. FIG. 4 shows substrate 302, amorphous layer 306, and taper 323. Annealing therefore results in a nucleation process initially confined to the nanotaper tip 312. The nanoscale geometrical confinement at nanotaper tip 312 and sharp tip radius facilitates the formation of a single nucleus 322. Single nucleus 322 is between amorphous substrate 306 and a volume of Sn-rich liquid 321.

Once a single nucleus is formed at the tip of the GeSn nanotaper, GeSn can grow laterally from this nucleus and transform the entire structure into single crystal. For example, in FIG. 4, GeSn grows laterally from nucleus 322 to transform amorphous GeSn to a single-crystal semiconductor shape 320. Sn-rich liquid 321 facilitates atomic transport at low temperatures to enhance the lateral growth. Single-crystal GeSn semiconductor shape 320 is similar to single-crystal semiconductor shape 220, FIG. 1, and includes a nanotaper 323 with tip 322. Once recrystallized and tin liquid 321 atop the shape solidifies, the tin may in some embodiments be stripped with a selective etch, in other embodiments the tin is allowed to remain as an electrically conductive, metallic, top contact to GeSn semiconductor shape 320.

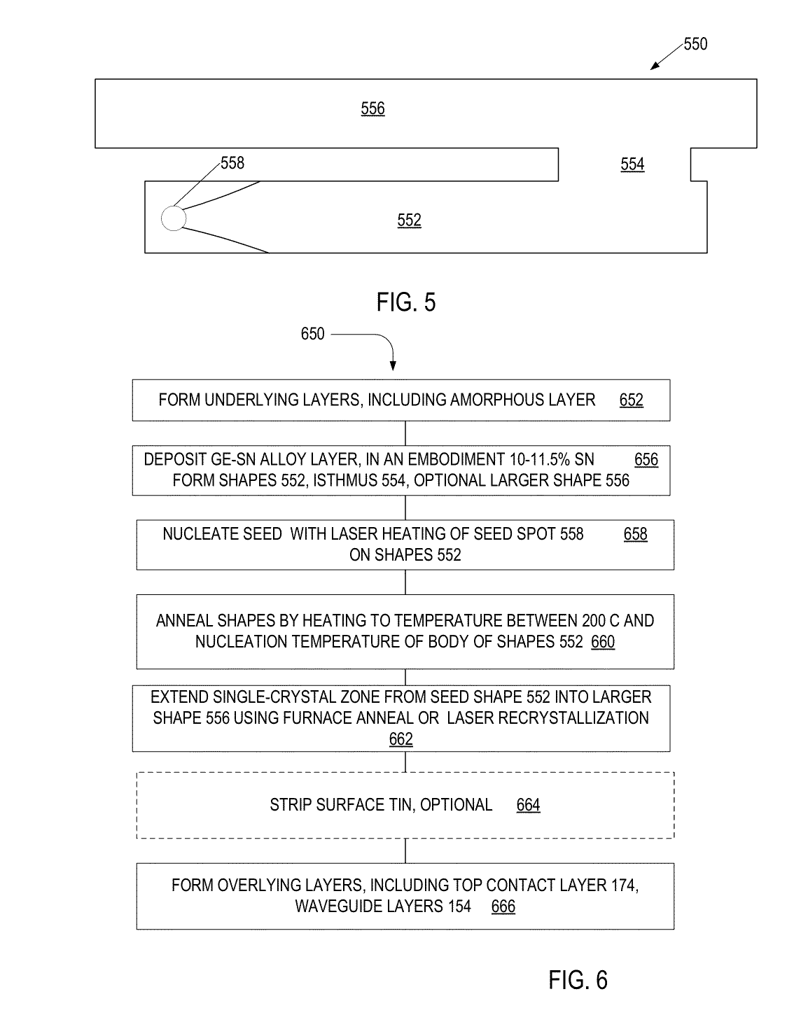

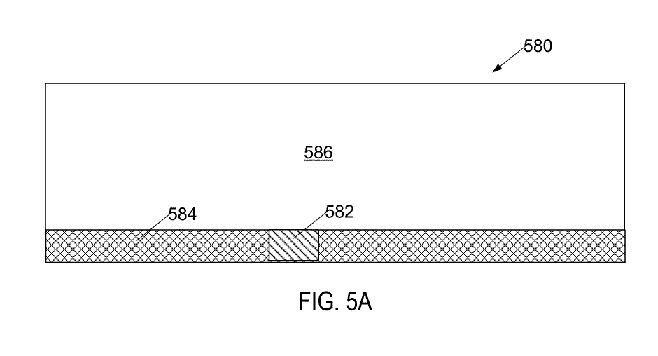

In an alternative embodiment 550, as illustrated as a top plan view in FIG. 5, a shape 552, which may be a nanotaper shape or may be a narrow rectangular shape with width less than 20 microns, is formed on an amorphous layer similar to the amorphous layer 134 of FIG. 2. The shape is formed 650 (FIG. 6) by forming underlying layers 652, then depositing 656 GeSn material and performing photolithography. Shape 552 in some embodiments may communicate through an isthmus 554 with a larger shape 556. Crystallization in embodiment 550 is initiated by laser heating 658 of a small seed spot 558, the laser may be moved at 1 micron per second, which exudes a small droplet of tin on its surface as the seed spot 558 forms a crystal of a eutectic mix of germanium and tin. In an embodiment the seed spot is between one tenth and ten microns in diameter as measured in a plane of the GeSn layer; in a particular embodiment the seed spot is one micron in diameter as measured in the plane of the GeSn layer. In an alternative embodiment having slightly higher power, the laser is moved at 50 microns per second.

The entire wafer is then annealed 660 at 440° C. for 30 minutes to allow the single crystal seed to serve as a seed as recrystallization spreads throughout shape 552 and isthmus 554 into larger shape 556.

In some embodiments having large shapes 580 (FIG. 5A), after deposition a seed spot is formed by laser heating a seed spot 582 of size between 1 and 10 microns, and in a particular embodiment one micron, diameter as measured in a plane of the GeSn layer. The seed spot is extended into a single-crystal seed line 584 by laser heating a laser-heated spot initially adjacent seed spot 582 and drawn along the line at, in a particular embodiment, a speed of 50 microns per second. The seed line 584 is then extended across remaining portions 586 of shape 580 by either annealing the shape in a conventional furnace, or by laser recrystallization using a heated line initially adjacent to seed line 584 and drawn away from line 584 across the remaining portions 586.

For smaller shapes 552, 556, the single crystal shape 552 may be used as a seed for furnace annealing at a temperature below the critical temperature of nucleation, this anneal is done at a temperature between 200° C. and 430° C. In order to allow for the possibility of larger shape 556 having nucleated to form a seed despite its having been kept below the critical temperature of nucleation, in some large-shape embodiments instead of a furnace anneal, the single-crystal shape 552 is used as a seed for laser recrystallization 662 (as known in the semiconductor art) of the entire larger shape 556 by forming a heated line across shape 556 near isthmus 554 and sweeping that line across shape 556. Surface tin may then be stripped 664 with an acid bath if surface tin is not desired. Overlying layers may then be formed 666, typically including top contacts and protection layers.

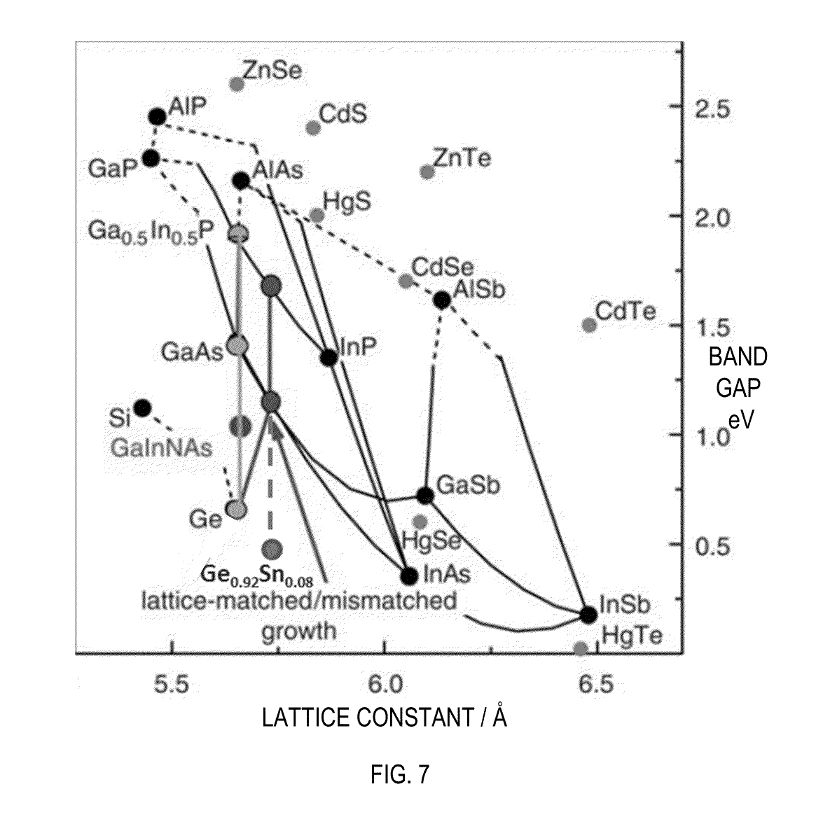

As can be seen in FIG. 7, for certain ratios of indium and gallium in indium gallium arsenide (InGaAs), GeSn has a good lattice match to InGaAs. Similarly, for certain ratios of gallium and indium in gallium indium phosphide (InGaP), GeSn has a good lattice match to InGaP.

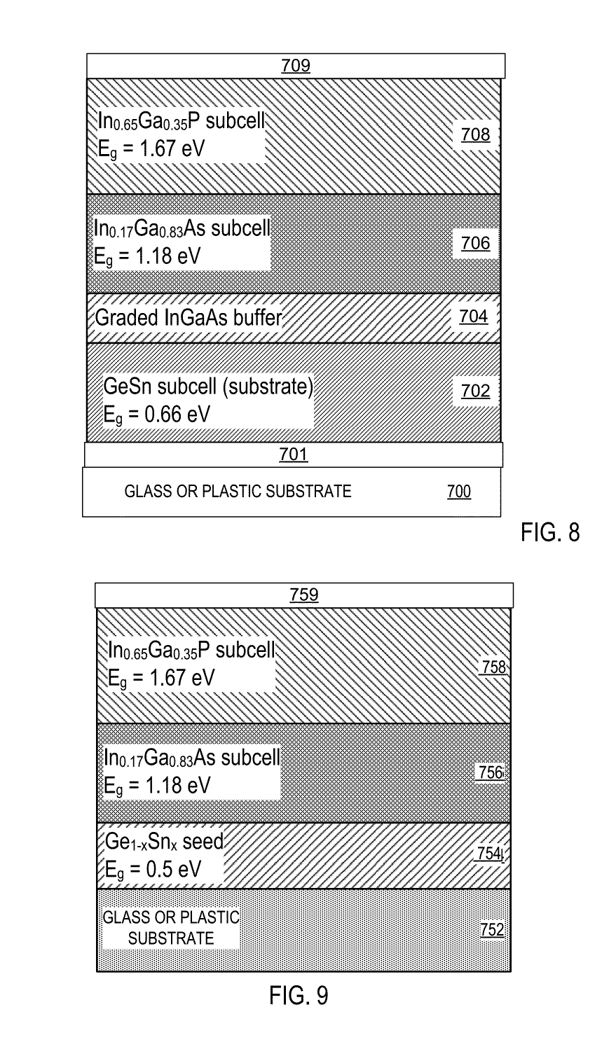

FIG. 8 is a cross sectional illustration of a three-layer photovoltaic cell illustrating a GeSn semiconductor layer 702 having a P-N junction (not shown) responsible for responding to long wavelength infrared radiation on a glass or plastic substrate 700, preferably with an amorphous metal back contact 701. In an alternative embodiment, substrate 700 is a metal substrate that may be insulated with an insulation layer (not shown). This cell also may have a graded InGaAs buffer layer 704, and an InGaAs layer 706 with a P-N junction for responding to mid-wavelength radiation, and a InGaP active layer 708 with a P-N junction for responding to short wavelength radiation. A transparent conductor layer 709 is provided as a top contact. The GeSn layer is formed and crystalized as a large area shape 556 as described with reference to FIG. 5, or 580 of FIG. 5A, and the other semiconductor layers are formed by epitaxial growth.

FIG. 9 is a cross sectional illustration of a tandem photovoltaic cell having InGaAs and InGaP active layers, with a GeSn seed layer 754 on glass or plastic substrate 752; in an alternative embodiment substrate 752 is a metal substrate with an optional insulation layer (not shown). In this photovoltaic cell, the GeSn layer 754 is formed and crystalized as a large area shape 556 as described with reference to FIG. 5, and the other semiconductor layers are formed by epitaxial growth. In an embodiment, InGaAs layer 756 with a P-N junction for responding to mid-wavelength radiation, and a InGaP active layer 758 with a P-N junction for responding to short wavelength radiation are grown atop the GeSn layer 754. A transparent conductor layer 759 is grown on top of the cell to provide electrical contact. In alternative embodiments, upper cells are Shottky-barrier photodiodes with InGaAs 756 and InGaP 758 absorber layers.

In a particular embodiment, layer InGaP layer 708, 758 of the tandem photovoltaic cell absorbs visible light from the blue 300 nm to the red at 750 nm wavelength, the InGaAs layer 706, 756 absorbs light from the red at 740 nm through the near infrared at 1000 nm wavelength, and the GeSn layer 702, 754 absorbs medium-infrared light from 1 micron to 2.5 micron wavelengths. In other alternative embodiments, InGaAs layer 756 or InGaP 758 layers are omitted, forming a two-layer tandem photodiode. In alternative embodiments, additional electronics are provided to balance photocurrent between layers of the tandem photovoltaic cell to optimize efficiency.

Once deposited, any of the GaSn, InGaP, and InGaAs semiconductor layers described herein may be doped to N or P type using ion implantation as known in the semiconductor art.

Further detail of the process described herein may be found in Pseudo single crystal, direct-band-gap Ge0.89Sn0.11 on amorphous dielectric layers towards monolithic 3D photonic integration, Haofeng Li Jeremy Brouillet, Xiaoxin Wang, and Jifeng Liva, Applied Physics Letters 105, 201107 (2014) (published online 20 Nov. 2014), and Low Temperature Geometrically Confined Growth of Pseudo Single CrystallineGeSn on Amorphous Layers for Advanced Optoelectronics, H. F. Li, J. Brouillet, A. Salas, I. Chaffin, X. X. Wang, and J. F. Liu, ECS Transactions, 64 (6) 819-827 (2014), the contents of both articles are incorporated herein by reference.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A method for producing a single-crystal shape on amorphous materials on an integrated circuit or solar cell structure comprising:
depositing a first semiconductor layer comprising a first material comprising Germanium-Tin (GeSn) alloy comprising between three and sixteen atomic percent tin, the GeSn alloy deposited on a second material, the second material incapable of seeding crystal formation in the GeSn alloy;
forming the shape, the shape having a point having radius less than 100 nanometers; and
annealing the shape by heating the integrated circuit to a temperature below 450 degrees Celsius.

2. The method of claim 1 wherein the GeSn alloy comprises between ten and eleven and a half percent tin.

3. The method of claim 2 wherein forming the shape is performed by photolithography.

4. The method of claim 2 wherein forming the shape is performed by laser scribing.

5. The method of claim 2 wherein the GeSn layer is between one and one thousand nanometers thick.

6. The method of claim 5 further comprising forming a waveguide adjacent to the shape.

7. The method of claim 5 wherein the second material is electrically conductive and further comprising depositing a third electrically conductive material on the shape.

8. The method of claim 7 further comprising fabricating in the shape an optoelectronic device selected from the group consisting of a photodiode, an electro-absorption modulator, a light emitting diode, and a laser.

9. The method of claim 5 further comprising depositing on the shape a second semiconductor layer comprising a fourth material comprising a semiconductor selected from InGaP and InGaAs, and configuring the shape as a tandem photodiode.

10. A method for producing a single-crystal layer on first amorphous or microcrystaline material comprising:
depositing a layer of a second material comprising Germanium-Tin (GeSn) alloy comprising between three and sixteen atomic percent tin;
defining a shape in the layer of GeSn alloy;
using a laser to heat and crystalize a seed spot on the shape; and
crystalizing additional GeSn alloy of the shape by a method selected from annealing the shape by heating the substrate to a temperature below 450 degrees Celsius and laser recrystalization.

11. The method of claim 10 wherein the seed spot is between one tenth and ten microns in diameter.

12. The method of claim 11 wherein the seed spot is about one micron in diameter.

13. The method of claim 11 wherein forming the shape is performed by photolithography.

14. The method of claim 11 wherein forming the shape is performed by laser scribing.

15. The method of claim 11 wherein the GeSn layer is between one and one thousand nanometers thick.

16. The method of claim 15 wherein the first material is electrically conductive and further comprising depositing a third electrically conductive material on the shape.

17. The method of claim 16 further comprising fabricating in the shape an optoelectronic device selected from the group consisting of a photodiode, an electro-absorption modulator, a light emitting diode, and a laser.

18. The method of claim 15 further comprising depositing on the shape a second semiconductor layer comprising a semiconductor selected from InGaP and InGaAs, and configuring the shape as a tandem photodiode.

19. The method of claim 15 further comprising depositing on the shape a second semiconductor layer comprising indium gallium arsenide (InGaAs), the InGaAs seeded by the GeSn, and a third semiconductor layer comprising indium gallium phosphide (InGaP), the InGaP seeded by the InGaAs.

20. The method of claim 19 wherein the GeSn, InGaP, and InGaAs form active layers of a tandem photovoltaic cell.

21. The method of claim 10 wherein the GeSn comprises between ten and eleven and a half atomic-percent tin.
